(19) United States
(12) Patent Application Publication
(10) Pub. No.: US 2026/0126500 A1
(43) Pub. Date: May 7, 2026

(54) ELECTRICAL MEASUREMENT DEVICES, SYSTEMS, AND METHODS

(71) Applicant: Power Probe Group, Inc., Charlotte, NC (US)

(72) Inventor: David Douglas Barden, Crestline, CA (US)

(73) Assignee: Power Probe Group, Inc., Charlotte, NC (US)

(21) Appl. No.: 18/935,838

(22) Filed: Nov. 4, 2024

(51) Int. Cl. G01R 31/74; G01R 31/00

(52) U.S. Cl. CPC G01R 31/74; G01R 31/006

(57) ABSTRACT

Electrical measurement devices, systems, and methods receive user input(s) selecting an electrical element from a list of electrical elements, each electrical element of the list of electrical elements having an impedance associated therewith. Impedance data of the electrical element's impedance is accessed from a data storage location. Voltage drop across an in-circuit electrical path passing through the electrical element is measured in response to a first conductive probe element of an electrical measurement device being in contact with a first terminal of the electrical element and a second conductive probe element of the electrical measurement device being in contact with a second terminal of the electrical element. Amperage of the electrical element is determined by the processor of the electrical measurement device from the voltage drop and the impedance, and a signal is transmitted to one or more indicators for indicating a status of the electrical element.

### FIELD OF THE INVENTION

This invention relates generally to electrical measurements, and more particularly, embodiments of the invention relate to an electrical measurement devices, systems, and methods.

### BACKGROUND OF THE INVENTION

A fuse is designed to provide overcurrent protection of an electrical circuit such that when too much current passes through, a metal strip or wire filament will melt or otherwise break thereby interrupting the circuit. Thus, a fuse is designed to protect more costly and important devices in the circuit. Example fuse elements that are designed to melt or otherwise break can include aluminum, copper, zinc, silver, or alloys of these metals. Different fuses can have differing voltage and current ratings, breaking capacity, response times, etc. Automotive or vehicle fuses are used to protect various electrical equipment within a vehicle. A vehicle typically has two fuse boxes/panels that house a number of automotive or vehicle fuses.

When an electrical component of a vehicle stops working, one method currently used to identify whether a fuse is “blown” such that the metal filament has melted/broken, each fuse may be removed and visually inspected to see if the metal filament is intact or broken. There may be black or gray discoloration as well that would indicate that the metal filament is broken.

Another way to test a fuse is with a multimeter. A multimeter is a multi-purpose electronic measuring instrument that performs various functions including an ammeter, a voltmeter, an ohmmeter, etc. Typically, a fuse needs to be removed in order to check it with a multimeter, and a user uses one hand to hold a test probe that contacts one terminal of the fuse and uses another hand to hold a separate test probe that contacts the other terminal of the fuse. This process can be inefficient, cumbersome, and time consuming. This process can create unnecessary inefficiencies for vehicle technician that regularly test fuses.

Thus, a need exists for improved devices, systems, and methods for performing measurements on fuses.

### BRIEF SUMMARY

Shortcomings of the prior art are overcome, and additional advantages are provided, through the provision of a method that includes receiving, by a processor of an electrical measurement device, one or more user inputs selecting an electrical element from a list of electrical elements. Each electrical element of the list of electrical elements has an impedance associated therewith. The method also includes accessing, from a data storage location, impedance data of the electrical element's impedance. Voltage drop across an in-circuit electrical path passing through the electrical element is measured in response to a first conductive probe element of the electrical measurement device being in contact with a first terminal of the electrical element and a second conductive probe element of the electrical measurement device being in contact with a second terminal of the electrical element. Using the processor of the electrical measurement device, and from the voltage drop and the impedance, amperage of the electrical element is determined, and a signal is transmitted to one or more indicators for indicating a status of the electrical element.

Also disclosed herein is an electrical measurement device that includes a first conductive probe element and a second conductive probe element. The electrical measurement device also includes a processor in electrical communication with the first conductive probe element and the second conductive probe element, a communication interface communicatively coupled to the processor, and a data storage location communicatively coupled to the processor. The data storage location stores executable code that, when executed, causes the processor to receive one or more user inputs selecting an electrical element from a list of electrical elements, each electrical element of the list of electrical elements having an impedance associated therewith. Impedance data of the electrical element's impedance are accessed from the data storage location, and voltage drop across an in-circuit electrical path passing through the electrical elements is measured in response to the first conductive probe element of the electrical measurement device being in contact with a first terminal of the electrical element and the second conductive probe element of the electrical measurement device being in contact with a second terminal of the electrical element. Amperage of the electrical element is determined from the voltage drop and the impedance, and a signal is transmitted to one or more indicators for indicating a status of the electrical element.

In addition, a system for measuring amperage of an electrical element. The system includes a processor, a communication interface communicatively coupled to the processor, and a data storage location communicatively coupled to the processor and storing executable code that, when executed, causes the processor to receive one or more user inputs selecting the electrical element from a list of electrical elements, each electrical element of the list of electrical elements having an impedance associated therewith. Further, impedance data of the electrical element's impedance are accessed from the data storage location. In addition, voltage drop across an in-circuit electrical path passing through the electrical element is measured in response to a first conductive probe element of an electrical measurement device being in contact with a first terminal of the electrical element and a second conductive probe element of the electrical measurement device being in contact with a second terminal of the electrical element. From the voltage drop and the impedance, amperage of the electrical element is determined, and a signal is transmitted to one or more indicators for indicating a status of the electrical element.

Additional features and advantages are realized through the concepts described herein.

### BRIEF DESCRIPTION OF THE DRAWINGS

One or more aspects are particularly pointed out and distinctly claimed as examples in the claims at the conclusion of the specification. The foregoing as well as objects, features, and advantages of one or more aspects are apparent from the following detailed description taken in conjunction with the accompanying drawings in which:

FIG. 1 is a perspective view of an electrical measurement device, according to an implementation of the present disclosure;

FIG. 2 is another perspective view of the electrical measurement device of FIG. 1, according to an implementation of the present disclosure;

FIG. 3 is a top view of the electrical measurement device of FIGS. 1-2, according to an implementation of the present disclosure;

FIG. 4A depicts a portion of a fuse voltage drop chart for a standard fuse, according to an implementation of the present disclosure;

FIG. 4B depicts another portion of the fuse voltage drop chart of FIG. 4A, according to an implementation of the present disclosure;

FIG. 5A depicts a portion of a fuse voltage drop chart of a mini fuse, according to an implementation of the present disclosure;

FIG. 5B depicts a portion of the fuse voltage drop chart of FIG. 5A, according to an implementation of the present disclosure;

FIG. 6A depicts a portion of a fuse voltage drop chart of a maxi fuse, according to an implementation of the present disclosure;

FIG. 6B depicts a portion of the fuse voltage drop chart of FIG. 6A, according to an implementation of the present disclosure;

FIG. 7A depicts a portion of a fuse voltage drop chart of a micro fuse, according to an implementation of the present disclosure;

FIG. 7B depicts a portion of the fuse voltage drop chart of FIG. 7A, according to an implementation of the present disclosure;

FIG. 8A depicts a portion of a fuse voltage drop chart of a JCASE™ cartridge style fuse, according to an implementation of the present disclosure;

FIG. 8B depicts a portion of the fuse voltage drop chart of FIG. 8A, according to an implementation of the present disclosure;

FIG. 9A depicts a portion of a fuse voltage drop chart of a glass fuse, according to an implementation of the present disclosure;

FIG. 9B depicts a portion of the fuse voltage drop chart of FIG. 9A, according to an implementation of the present disclosure;

FIG. 10 depicts a block diagram of an example method, according to an implementation of the present disclosure;

FIG. 11A depicts a perspective view of an electrical measurement device in combination with a sleeve, according to an implementation of the present disclosure;

FIG. 11B depicts another perspective view of the electrical measurement device in combination with the sleeve of FIG. 11A, according to an implementation of the present disclosure;

FIG. 11C depicts another perspective view of the electrical measurement device in combination with the sleeve of FIGS. 11A-11B, according to an implementation of the present disclosure;

FIG. 11D depicts another perspective view of the electrical measurement device in combination with the sleeve of FIG. 11A-11C, according to an implementation of the present disclosure;

FIG. 11E depicts another perspective view of the electrical measurement device in combination with the sleeve of FIG. 11A-11D, according to an implementation of the present disclosure;

FIG. 11F depicts another perspective view of the electrical measurement device in combination with the sleeve of FIG. 11A-11E, according to an implementation of the present disclosure;

FIG. 11G depicts another perspective view of the electrical measurement device in combination with the sleeve of FIG. 11A-11F, according to an implementation of the present disclosure;

FIG. 11H depicts another perspective view of the electrical measurement device in combination with the sleeve of FIG. 11A-11G, according to an implementation of the present disclosure;

FIG. 11I depicts a side view of the electrical measurement device in combination with the sleeve of FIG. 11A-11H, according to an implementation of the present disclosure;

FIG. 11J depicts a back view of the electrical measurement device in combination with the sleeve of FIG. 11A-11I, according to an implementation of the present disclosure;

FIG. 11K depicts a side view of the electrical measurement device in combination with the sleeve of FIG. 11A-11J, according to an implementation of the present disclosure;

FIG. 11L depicts a front view of the electrical measurement device in combination with the sleeve of FIG. 11A-11K, according to an implementation of the present disclosure;

FIG. 11M depicts a top view of the electrical measurement device in combination with the sleeve of FIG. 11A-11L, according to an implementation of the present disclosure;

FIG. 11N depicts a bottom view of the electrical measurement device in combination with the sleeve of FIG. 11A-11M, according to an implementation of the present disclosure;

FIG. 12A depicts a perspective view of an electrical measurement device, according to an implementation of the present disclosure;

FIG. 12B depicts another perspective view of the electrical measurement device of FIG. 12A, according to an implementation of the present disclosure;

FIG. 12C depicts another perspective view of the electrical measurement of FIGS. 12A-12B, according to an implementation of the present disclosure;

FIG. 12D depicts another perspective view of the electrical measurement device of FIG. 12A-12C, according to an implementation of the present disclosure;

FIG. 12E depicts another perspective view of the electrical measurement device of FIG. 12A-12D, according to an implementation of the present disclosure;

FIG. 12F depicts another perspective view of the electrical measurement device of FIG. 12A-12E, according to an implementation of the present disclosure;

FIG. 12G depicts another perspective view of the electrical measurement device of FIG. 12A-12F, according to an implementation of the present disclosure;

FIG. 12H depicts another perspective view of the electrical measurement device of FIG. 12A-12G, according to an implementation of the present disclosure;

FIG. 12I depicts a side view of the electrical measurement device of FIG. 12A-12H, according to an implementation of the present disclosure;

FIG. 12J depicts a back view of the electrical measurement device of FIG. 12A-12I, according to an implementation of the present disclosure;

FIG. 12K depicts a side view of the electrical measurement device of FIG. 12A-12J, according to an implementation of the present disclosure;

FIG. 12L depicts a front view of the electrical measurement device of FIG. 12A-12K, according to an implementation of the present disclosure;

FIG. 12M depicts a top view of the electrical measurement device of FIG. 12A-12L, according to an implementation of the present disclosure; and

FIG. 12N depicts a bottom view of the electrical measurement device of FIG. 12A-12M, according to an implementation of the present disclosure.

### DETAILED DESCRIPTION

Aspects of the present invention and certain features, advantages, and details thereof are explained more fully below with reference to the non-limiting examples illustrated in the accompanying drawings. It is to be understood that the disclosed embodiments are merely illustrative of the present invention and the invention may take various forms. Further, the figures are not necessarily drawn to scale, as some features may be exaggerated to show details of particular components. Thus, specific structural and functional details illustrated herein are not to be interpreted as limiting, but merely as a representative basis for teaching one skilled in the art to employ the present invention.

Descriptions of well-known processing techniques, systems, components, etc. may be omitted to not unnecessarily obscure the invention in detail. It should be understood that the detailed description and the specific examples, while indicating aspects of the invention, are given by way of illustration only, and not by way of limitation. Various substitutions, modifications, additions, and/or arrangements, within the spirit and/or scope of the underlying inventive concepts will be apparent to those skilled in the art from this disclosure. Additionally, numerous inventive aspects and features are disclosed herein, and unless inconsistent, each disclosed aspect or feature is combinable with any other disclosed aspect or feature as desired for a particular embodiment of the concepts disclosed herein.

The specification may include references to “one embodiment”, “an embodiment”, “various embodiments”, “one or more embodiments”, etc. may indicate that the embodiment(s) described may include a particular feature, structure or characteristic, but every embodiment may not necessarily include the particular feature, structure, or characteristic. In some cases, such phrases are not necessarily referencing the same embodiment. When a particular feature, structure, or characteristic is described in connection with an embodiment, such description can be combined with features, structures, or characteristics described in connection with other embodiments, regardless of whether such combinations are explicitly described.

The terms “couple,” “coupled,” “couples,” “coupling,” and the like should be broadly understood to refer to connecting two or more elements or signals electrically and/or mechanically, either directly or indirectly through intervening circuitry and/or elements. Two or more electrical elements may be electrically coupled, either direct or indirectly, but not be mechanically coupled; two or more mechanical elements may be mechanically coupled, either direct or indirectly, but not be electrically coupled; two or more electrical elements may be mechanically coupled, directly or indirectly, but not be electrically coupled. Coupling (whether only mechanical, only electrical, or both) may be for any length of time, e.g., permanent or semi-permanent or only for an instant. Additionally, “electrically coupled” and the like should be broadly understood and include coupling involving any electrical signal, whether a power signal, a data signal, and/or other types or combinations of electrical signals.

In addition, as used herein, the terms “about,” “approximately,” or “substantially” for any numerical values or ranges indicate a suitable dimensional tolerance that allows the device, part, or collection of components to function for its intended purpose as described herein. As used herein, the term “vehicle” is to be interpreted broadly to include any machine used to transport people or cargo including, for example, motor vehicles (e.g., motorcycles, cars, trucks, buses, mobility scooters, etc.), railed vehicles (e.g., trains, trams, etc.), watercraft (e.g., ships, boats, underwater vehicles, etc.), amphibious vehicles (e.g., hovercraft, screw-propelled vehicles, etc.), aircraft (e.g., airplanes, helicopters, etc.), and spacecraft.

Disclosed herein are electrical measurement devices, systems, and methods that have advantages over prior art devices, systems, and methods. For example, the disclosed measurement device has uniquely designed conductive probe elements (i.e., probes, leads, tips, etc.), which are cross-functional for different types of fuses. For instance, the conductive probe elements are designed to work effectively with standard fuses, mini fuses, maxi fuses, micro fuses, JCASE™ cartridge style fuses, and glass fuses. Many types of existing electrical measurement systems utilize interchangeable leads for different types of fuses, which can lead to lost or misplaced leads or lead attachments. Further, switching out the interchangeable leads can lead to inefficiencies that would need the attachments to be switched out for each of the different types of fuses. In addition, the disclosed electrical measurement devices, systems, and methods do not require a use to use two hands to hold each of the separate probes in order to contact the terminals of the fuse. This can be particularly burdensome in hard to access fuse boxes. Advantageously, the disclosed electrical measurement device is easier to use, more efficient for vehicle technicians, and less likely to have lost or misplaced leads when they get disconnected from the electrical measurement device. Accordingly, the clamping nature of the conductive probe elements provide an ergonomic, efficient, cross-functional, and fully integrated approach to facilitate electrical measurements.

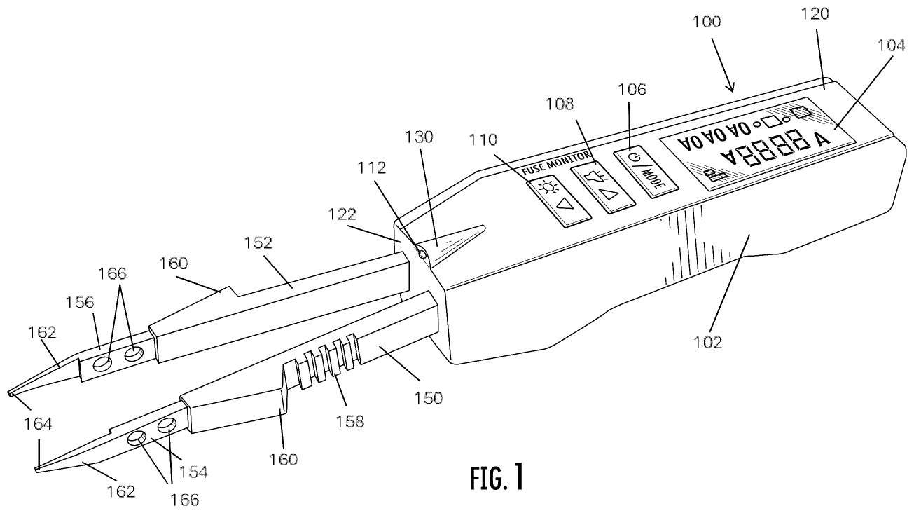

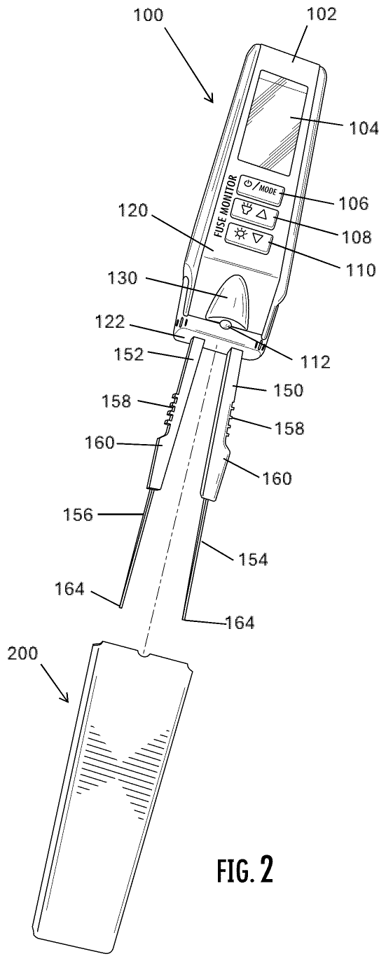

FIGS. 1-2 are perspective views of an electrical measurement device 100, in accordance with an embodiment of the present invention. The electrical measurement device 100, includes a housing 102 having a communication interface that includes a display screen 104 on the front face 120 thereof. The face of the housing 102 also includes a plurality of inputs 106, 108, 110. As depicted, the inputs 106, 108, 110 are selectable buttons, but in some embodiments, inputs may be incorporated into the screen itself (i.e., a touchscreen) or the inputs may include dials, knobs, sliders, switches, etc. In one embodiment, a first input 106 is for selecting a mode associated with the electrical element for which a measurement is being performed. In some instances, the first input 106 may also double as an on/off switch such that holding the button for a prolonged period of time may be used to turn off the electrical measurement device 100 (including the backlight of the display screen 104) or selecting the first input 106 may initially turn on the device and illuminate the backlight of the display screen 104. In some embodiments, the electrical measurement device 100 may automatically turn off after a predefined period of non-use. A second input 108 is also located on the face 120, where the second input 108 is for turning on or off a light emitting diode (LED) 112. A third input 110 is also located on the face 120, where the third input 110 is for adjusting the brightness of the backlight of the display screen 104.

As shown in FIG. 2, the electrical measurement device 100 is also configured to be at least partially housed within a sleeve 200. For example, the sleeve 200 may be configured to cover a first conductive probe element 150 and a second conductive probe element 152.

The electrical measurement device 100 also includes a first conductive probe element 150 and a second conductive probe element 152 that together form a pair of conductive probe elements 150, 152. The pair of conductive probe elements 150, 152 may extend outward from a bottom 122 of the housing 102. The LED 112 is useful as it is directed toward the pair of conductive probe elements 150, 152 to illuminate the area that the pair of conductive probe elements 150, 152 would be contacting. This can be advantageous in dark areas where the fuse box may be located. Specifically, the LED 112 may be positioned on the face 120 of the housing 102 and pointed in the direction of the bottom 122 and the pair of conductive probe elements 150, 152. In order to provide the needed visibility, the face 120 may include an outward projection or rise 130 in the surface of the face 120. In order to still provide a generally flat front face 120 even with the surface rise associated with the LED 112, the bottom portion of the front face 120 may be sloped down and back away from the front face 120 so that the rise 130 associated with the LED 112 protrudes outward from the face 120 generally at a same amount as the remaining portion of the front face 120.

The pair of conductive probe elements 150, 152 may include a soft material that encases much of a length of the pair of conductive probe elements 150, 152 starting proximate the bottom 122 and extending outward towards the conductive tips 154, 156 of each of the respective conductive probe elements 150, 152. The soft material on each conductive probe element 150, 152 may include ridges 158 for enhancing a person's grip. Further, the soft material may include outward facing protrusions 160 that provide an ergonomically designed resting position for the user's fingers. The conductive tips 154, 156 may be a metallic material and may each have a tapered end 162 that forms a point 164, which allows for a precise contact surface for contacting terminals of an electrical element such as a fuse. Advantageously, the conductive tips 154, 156 may initially be wide before tapering to the point 164, which provides more stability than a narrow wire. The width of the conductive tips 154, 156 would be less likely to bend or break during use when compared to a narrow wire. In some embodiments, the conductive tips 154, 156 include apertures 166.

The electrical measurement device 100 may incorporate various input-output (I/O) interfaces. According to one embodiment, the I/O interface may include a wireless connection such as a Bluetooth component or other wireless communication means for wirelessly connecting to an external computing device (e.g., a laptop, desktop computer, mobile computing device (i.e., smartphone), portable digital assistant, pager, virtual assistance device such as a smart speaker or other smart home device, or any combination of the aforementioned, or other portable device with processing and communication capabilities). In particular, the wireless communication means may be electrically coupled to the analyzer and the wireless communication means facilitates transmitting one or more readings from the analyzer across a network to an external computing device. The I/O interface may include the display screen, which may utilize, according to one example, a liquid crystal display (LCD), a light-emitting diode (LED) display, a thin-film transistor LCD, a quantum dot (QLED) display, an organic LED (OLED) display, etc. According to one embodiment, the I/O interface may incorporate a control panel for controlling functionality of the electrical measurement device 100.

The display screen 104 is configured to, and is capable of, displaying an output (e.g., amperage of the electrical element, such as a fuse, which is being tested) that is derived by a processor that is internal to the housing 102. According to various embodiments, the processor may be associated with an analyzer and may be part of a microcomputer, a microcontroller, an analog-to-digital converter (ADC), and/or a microprocessor. The analyzer may analyze data in order to identify a pattern or relationship. For instance, the analyzer may analyze data obtained from the sensor(s) (e.g., resistor(s)) in order to calculate or otherwise determine amperage.

Specifically, when pair of conductive probe elements 150, 152 come into contact with respective terminals of the electrical element, the sensor(s) may collect data of the voltage drop across an in-circuit electrical path passing through the electrical element. The processor that is communicatively coupled to the sensor(s) may access the impedance data of the electrical element identified by the user and calculate, using Ohm's law (i.e., V=IR, where V=voltage, I=current, and Z=impedance) what the amperage (i.e., current) is that is passing through the electrical element. In particular, the analyzer may receive analog signals, such as analog voltage signals/measurement of the voltage drop, and the analog-to-digital converter (ADC) may convert the analog signals to a digital signal or digital data. The digital data may then be provided from the ADC to the processor, which can perform further analysis, calculations, or formatting of the data.

The various components of the analyzer (e.g., processor, microprocessor, microcontroller, microcomputer, analog-to-digital converter, etc.) may utilize the output of the sensor(s) (e.g., resistor(s)) to generate an output signal to the display screen 104 that is representative of the output being measured. The analyzer may incorporate a circuit board assembly comprising a circuit board upon which a microprocessor and the display screen 104 may be connected. In some example embodiments, the analyzer may incorporate a processor that uses software algorithms to derive various information indicative of a parasitic draw of the electrical system of the vehicle from the fuse. In some embodiments, the analyzer is in communication with the display screen 104 that displays the amperage that has been derived from the voltage drop and the impedance of the electrical element selected.

According to one embodiment, the analyzer includes an ammeter and/or a voltmeter. The ammeter may include, for example, at least a 0.001 A resolution with the capacity to measure between 0 A-100 A depending upon the type of fuse. Further, the voltmeter may include, for example, at least a 0.1 mV resolution with a capacity to measure between 0 mV-10 mV.

In addition to a processor, the housing 102 includes therein a power source (e.g., a battery) configured to energize the electrical measurement device 100. According to various embodiments, the power source may include a rechargeable battery. Further, the power supply, microcontroller, display driver, and various other components may be interconnected within the housing 102.

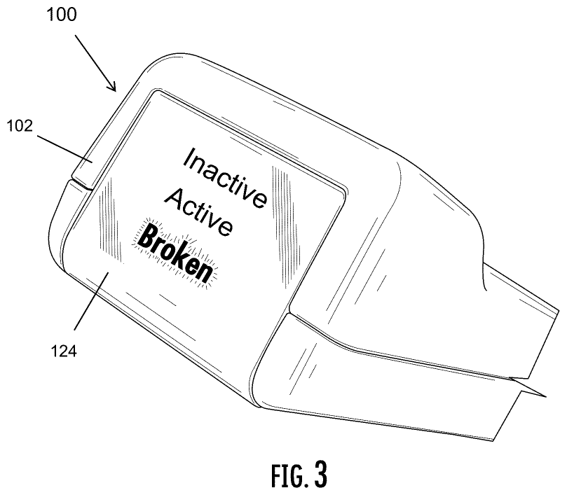

According to various embodiments, the analyzer may incorporate an analyzer system comprising various modules, where the modules perform different functionalities. In one example, the analyzer system may incorporate a voltage module for deriving voltage data. The analyzer may perform certain processing functionalities to detect various errors and provide various outputs for the errors. In particular, the analyzer may detect the status of the electrical element as being “Inactive,” which is indicative that there is no current going through the fuse, “Active,” which is indicative that there is current going through the fuse, and “Broken,” which is indicative that the fuse is broken. As depicted by FIG. 3, which is a top view of the electrical measurement device of FIGS. 1-2, one or more indicator lights located on the top 124 of the electrical measurement device 100 may provide a visual indication of a status (i.e., “Inactive,” “Active,” and “Broken”) of the electrical element. The one or more indicator lights may be configured as a LED, and more specifically a color changing LED that utilizes, for example, a green color to indicate that the status is “Inactive,” white/yellow to indicate that the status is “Active,” and red to indicate that the status is “Broken.”

Internal resistance of an electrical element causes resistance of the flow of charges going through the electrical element, where the resistance leads to a change in voltage (i.e., voltage drop) between two ends of the electrical element. Thus, the voltage drop is the difference in voltage of two terminals on the electrical element. By connecting a resistor in parallel with the electrical element, the voltage drop may be identified. For instance, the housing 102 may include one or more sensors (e.g., resistor(s)) that are coupled (e.g., connected in parallel) to the terminals of the electrical element.

The data storage location may store impedance data for many electrical elements, such as fuses, where the impedance data indicates the impedance of each electrical element. According to one embodiment, data may be stored, via a data storage location (e.g., random access memory (RAM), read-only memory (ROM), volatile memory such as a cache area for temporary storage of data, non-volatile memory that is embedded and/or removable such as electrically erasable programmable read-only memory (EEPROM), flash memory, or the like).

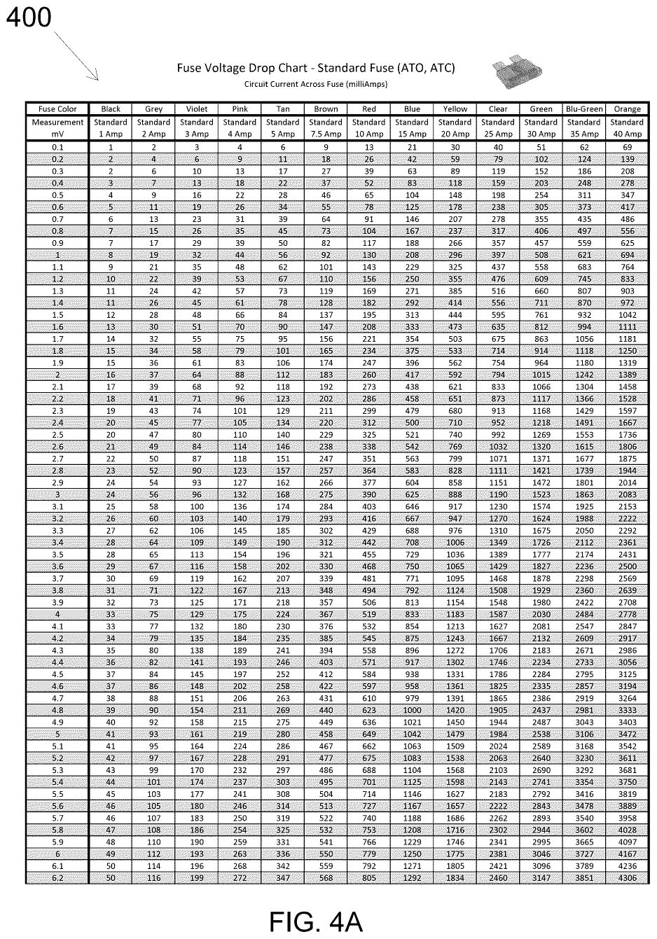

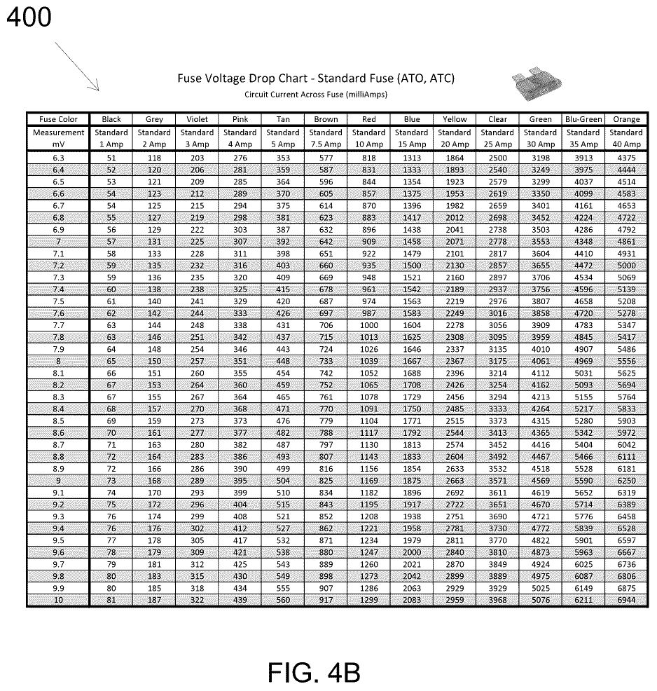

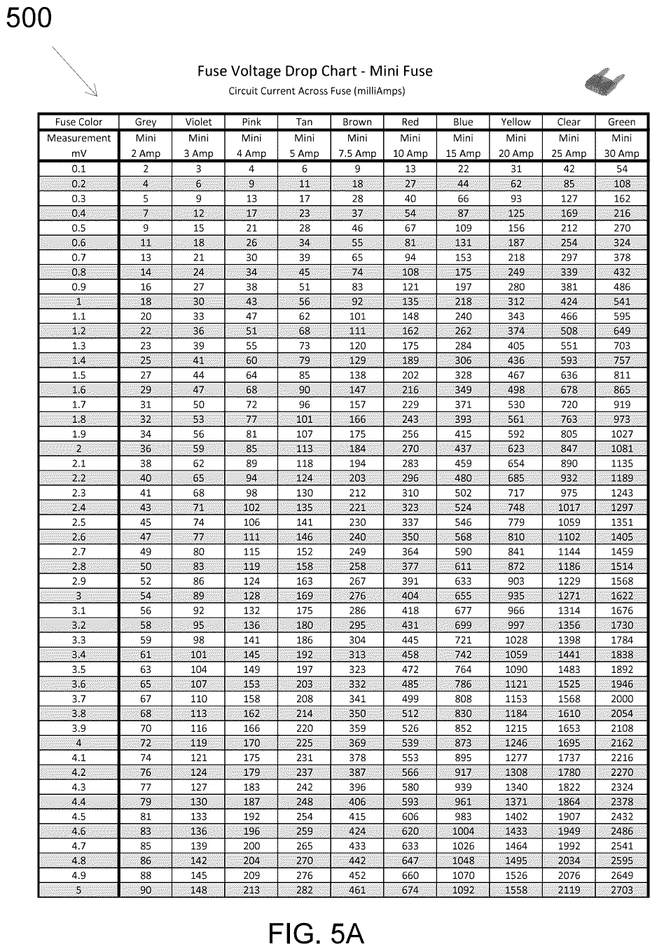

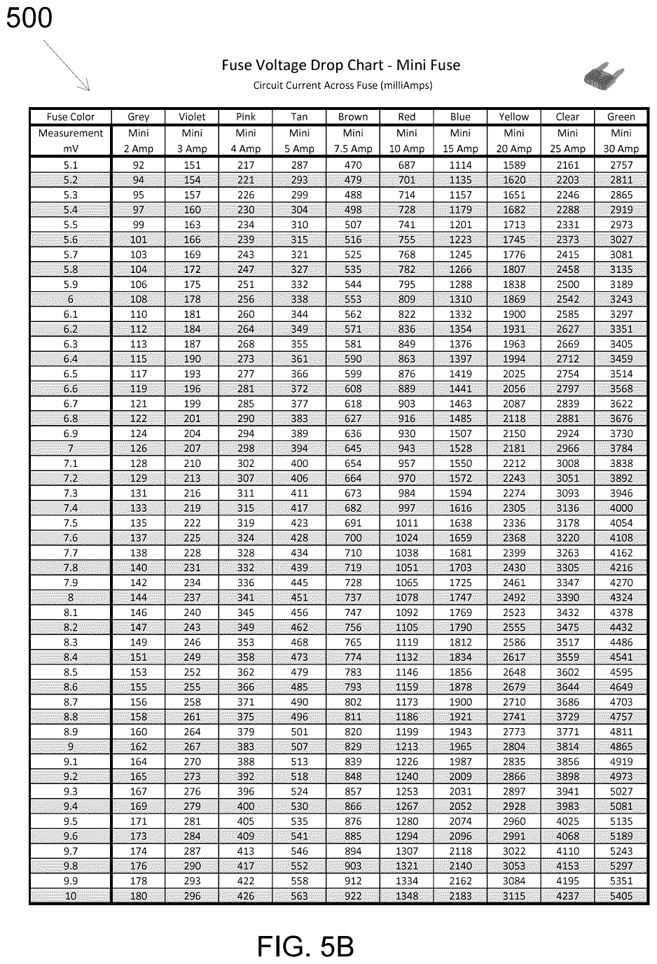

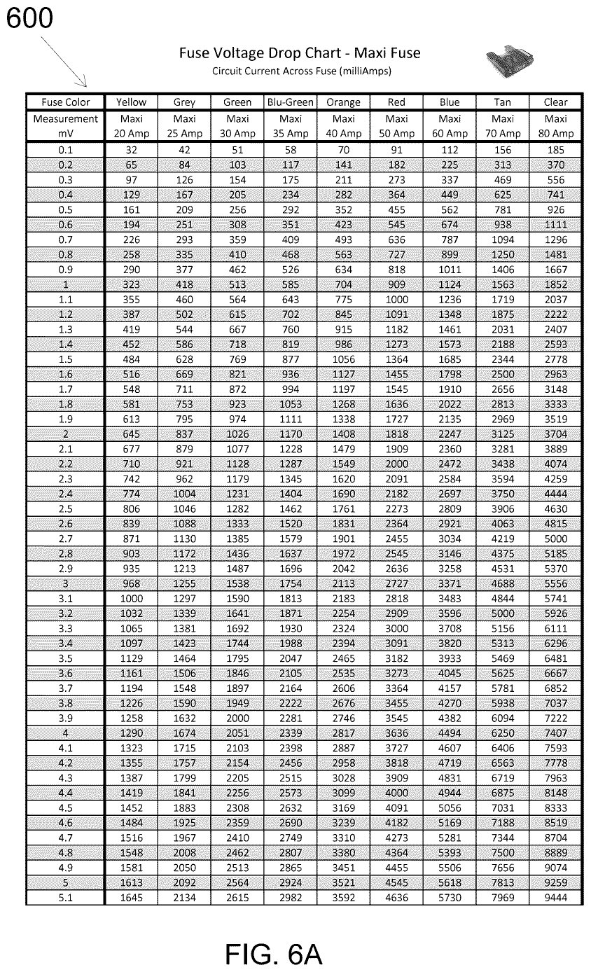

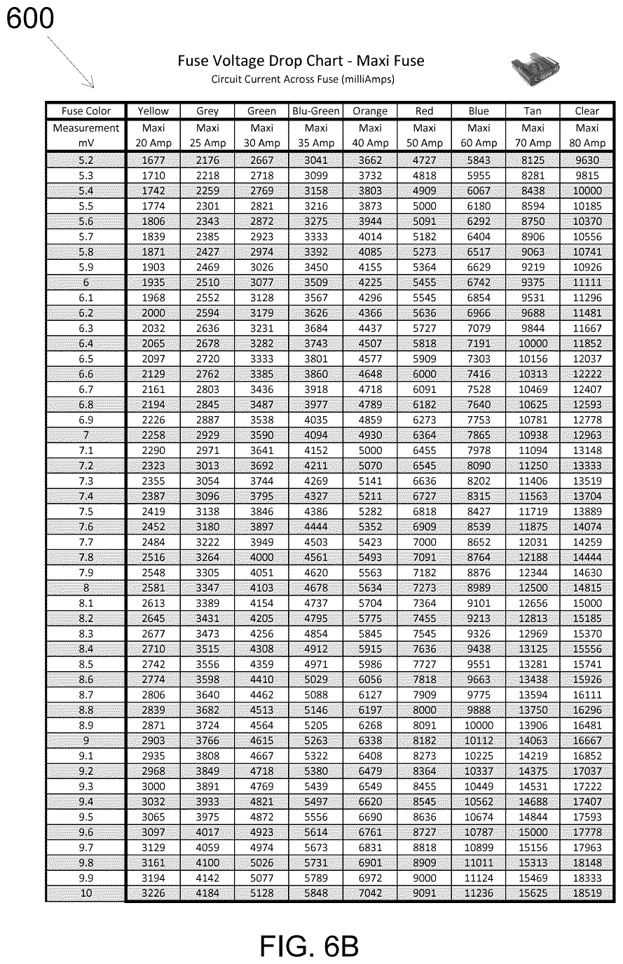

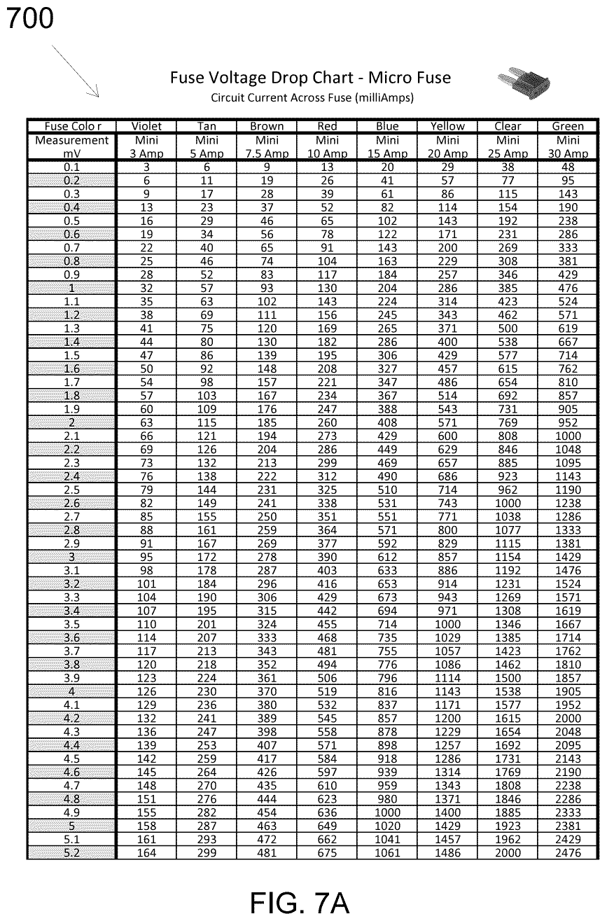

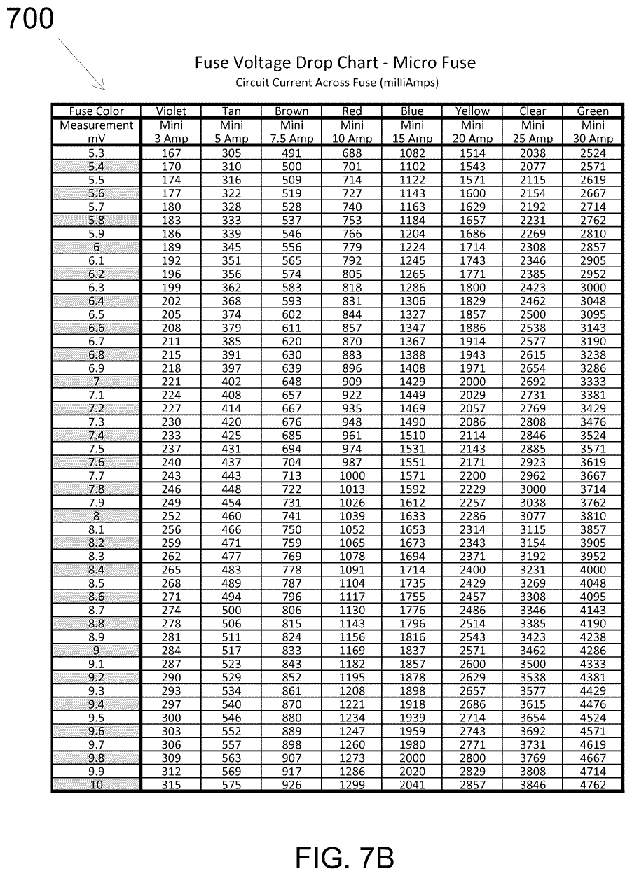

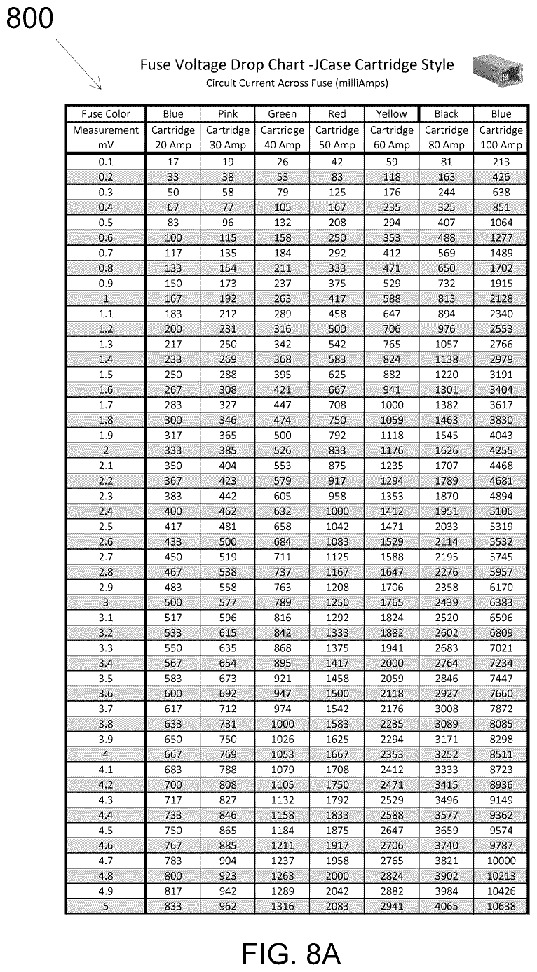

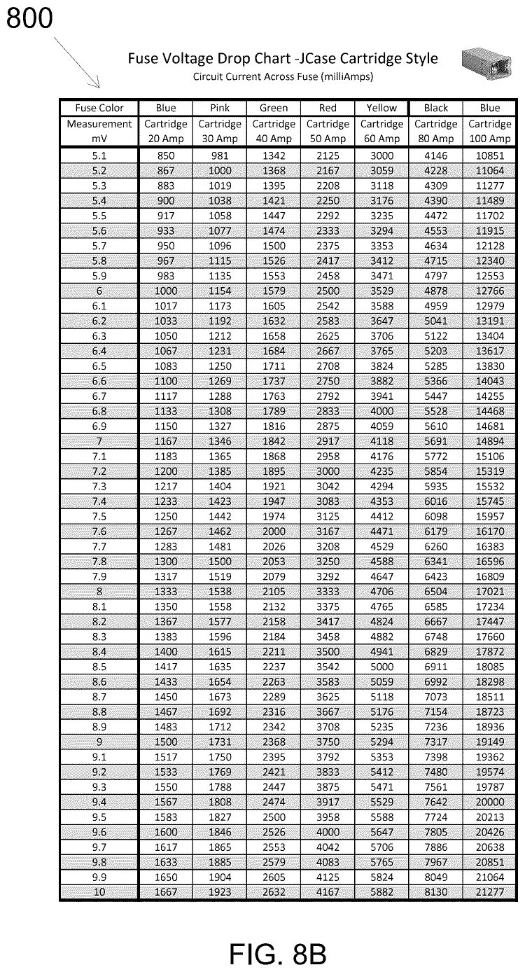

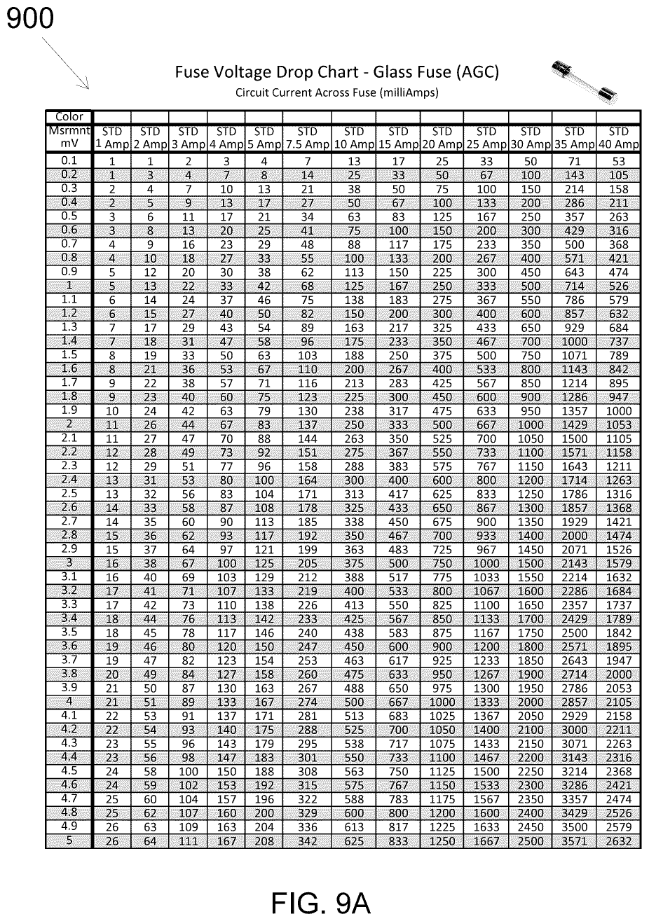

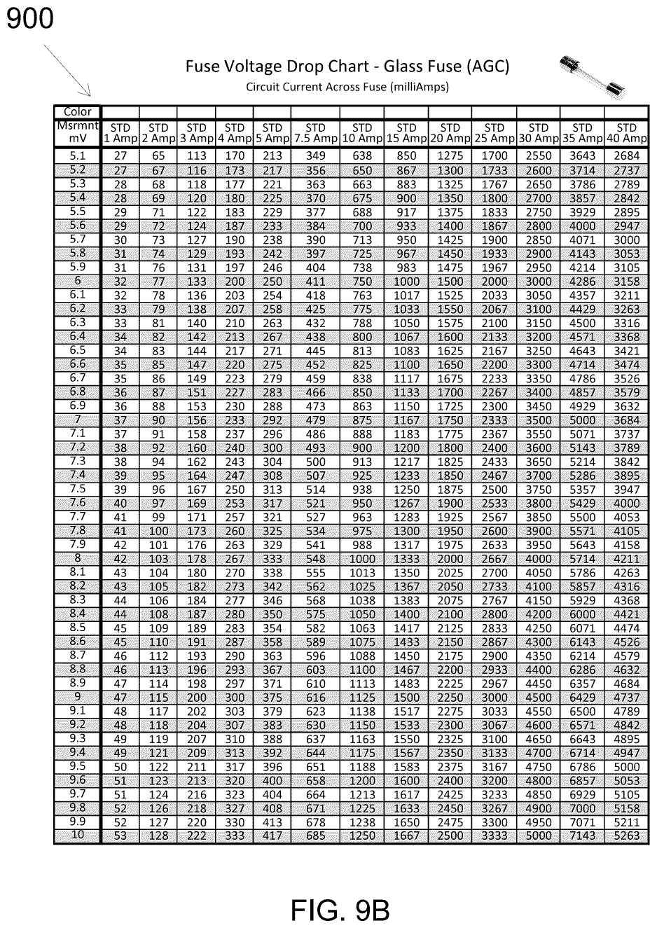

Specifically, the impedance data includes a plurality of voltage drop charts, and a user may toggle/scroll through each of the voltage drop charts to select the appropriate electrical element being measured. Data of each of the voltage drop charts depicted by FIGS. 4A-9B would be stored to the data storage location. Specifically, the fuse voltage drop charts include impedance data for a standard fuse, a mini fuse, a maxi fuse, a micro fuse. In addition, a user is able to select the fuse value within each fuse type in order to select the corresponding impedance for the fuse type and fuse value. FIGS. 4A-4B depict portions of a fuse voltage drop chart 400 for a standard fuse, according to one embodiment of the present invention. FIGS. 5A-5B depict portions of a fuse voltage drop chart 500 of a mini fuse, according to one embodiment of the present invention. FIGS. 6A-6B depict portions of a fuse voltage drop chart 600 of a maxi fuse, according to one embodiment of the present invention. FIGS. 7A-7B depict portions of a fuse voltage drop chart 700 of a micro fuse, according to one embodiment of the present invention. FIGS. 8A-8B depict portions of a fuse voltage drop chart 800 of a JCASE™ cartridge style fuse, according to one embodiment of the present invention. FIGS. 9A-9B depict portions of a fuse voltage drop chart 900 of a glass fuse, according to one embodiment of the present invention.

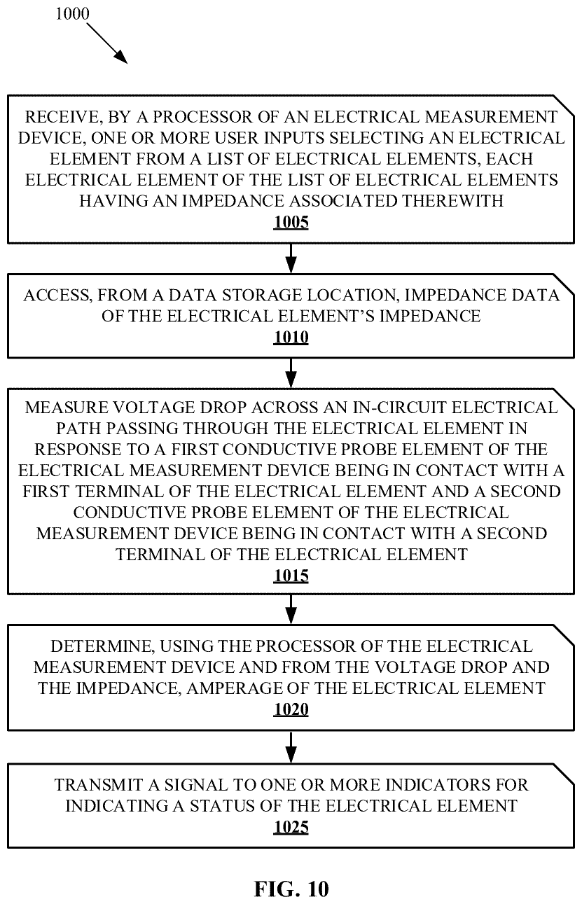

FIG. 10 depicts a block diagram of an example method 1000, according to an implementation of the present disclosure. At block 1005, the system receives, by a processor of an electrical measurement device, one or more user inputs selecting an electrical element from a list of electrical elements, each electrical element of the list of electrical elements having an impedance associated therewith. In some embodiments, the electrical element includes a vehicle fuse, the first terminal is a first fuse terminal, and the second terminal is a second fuse terminal. In some embodiments, the electrical measurement device includes a first input for selecting a mode associated with the electrical element, a second input for turning on or off a light emitting diode (LED), and a third input for adjusting the brightness of the backlight of the display screen. In some embodiments, a front face of a housing of the electrical measurement device includes a lighting element directed towards the first conductive probe element and the second terminal of the electrical element.

At block 1010, the system accesses, from a data storage location, impedance data of the electrical element's impedance. In some embodiments, the data storage location includes a database internal to the electrical measurement device. At block 1015, the system measures voltage drop across an in-circuit electrical path passing through the electrical element in response to a first conductive probe element of the electrical measurement device being in contact with a first terminal of the electrical element and a second conductive probe element of the electrical measurement device being in contact with a second terminal of the electrical element. In some embodiments, the first conductive probe element of the electrical measurement device and the second conductive probe element of the electrical measurement device are both at least partially integrated with the electrical measurement device itself.

At block 1020, the system determines, using the processor of the electrical measurement device and from the voltage drop and the impedance, amperage of the electrical element, and at block 1025, a signal is transmitted to one or more indicators for indicating a status of the electrical element. In some embodiments, the method 1000 further includes displaying, via a user interface of the electrical element, a numerical value of the amperage of the electrical element. In some embodiments, the one or more indicators include one or more indicator lights, where the one or more indicator lights provide a visual indication of the status of the electrical element, the status being selected from the group consisting of “Inactive,” “Active,” and “Broken.” In some embodiments, the one or more indicator lights incorporate a color-specific indication where a green color is associated with the “Inactive” status, a white/yellow color is associated with the “Active” status, and a red color is associated with the “Broken” status.

In some embodiments, an electronic measuring instrument may incorporate an electric multimeter in combination with a meter pen box, where the electric multimeter and the meter pen box each include at least four interconnected connection points (e.g., terminals, holes, etc.) where the different interconnected connection points form different functions. For example, one connection point may provide a grounding functionality, another connection point may be used to measure a relatively higher current amperage (e.g., 10 A), another connection point may be used to measure a relatively lower current amperage (e.g., 1 A), and another connection point may be used to create a composite measurement. The meter pen box may supplement the capabilities of the electric multimeter in order to provide a maximum measurement current of 30 A. The meter pen box may include modifiable current measurement modes through a logic circuit.

In this embodiment, an electronic measuring instrument (e.g., the meter pen box in combination with the multimeter) may measure voltage drop across an electrical path passing through an electrical element in response to a first conductive probe element of the electrical measurement device being in contact with a first terminal of the electrical element and a second conductive probe element of the electrical measurement device being in contact with a second terminal of the electrical element. The electronic measuring instrument determines from the voltage drop and an impedance value selected from one or more stored impedance values, amperage of the electrical element. An alert message may be transmitted to one or more communication interfaces for providing an indication of the amperage of the electrical element.

In some embodiments, systems and methods of identifying amperage includes measuring voltage drop across an in-circuit electrical path passing through an electrical element in response to a first conductive probe element that is coupled to an electrical measurement device being in contact with a first terminal of the electrical element and a second conductive probe element that is coupled to the electrical measurement device being in contact with a second terminal of the electrical element. Further, the method includes determining, using a processor of the electrical measurement device and from the voltage drop and from a stored impedance value corresponding to the electrical element, amperage of the electrical element. The method also includes transmitting a signal to one or more communication interfaces for communicating the amperage. In some embodiments, the range of the amperage is between 0 A-100 A, and more particularly between 0 A-80 A or between 0 A-30 A. In some embodiments, the stored impedance value is selected from impedance data of a plurality of impedance values stored to one or more data storage locations. Further, the stored impedance value may be selected based on receiving one or more user inputs identifying the electrical element.

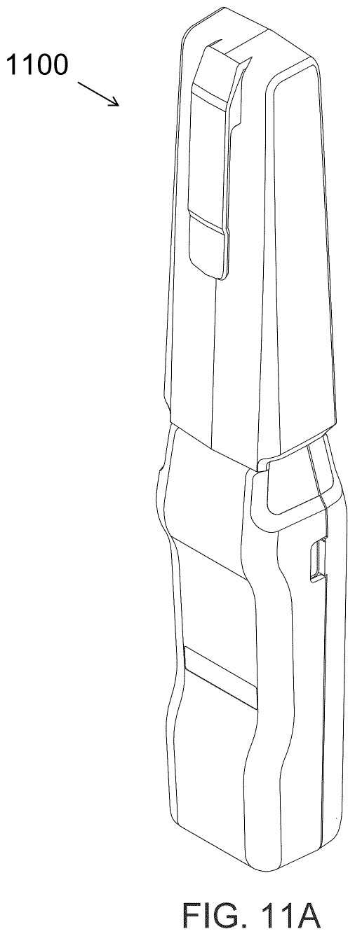

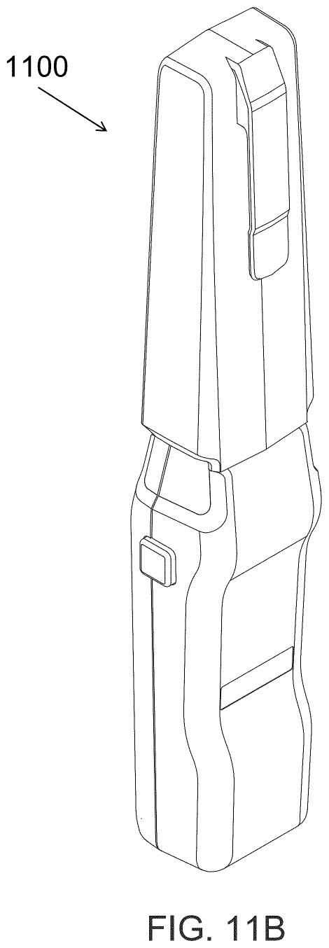

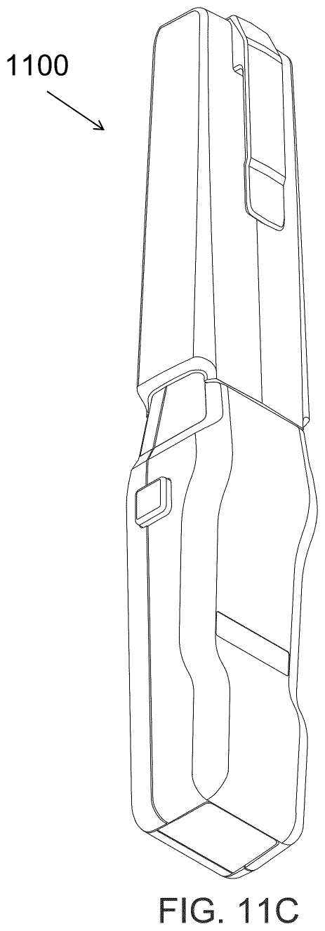

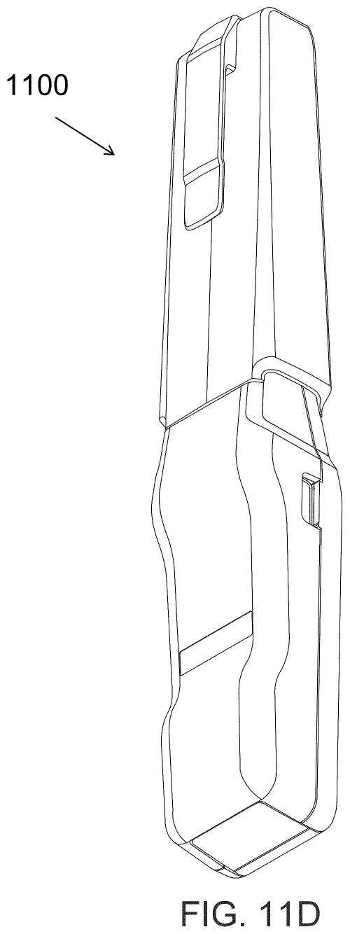

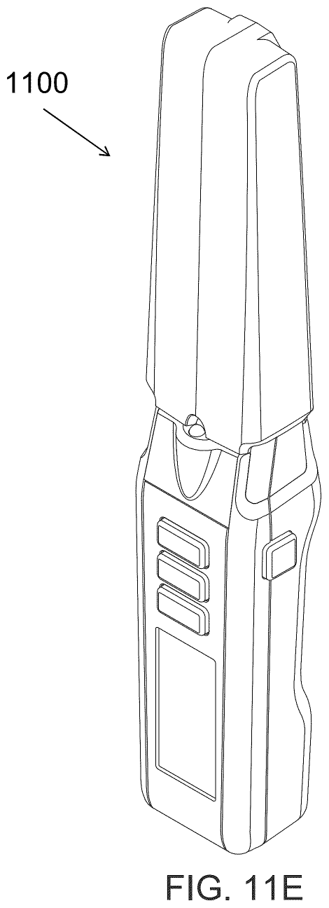

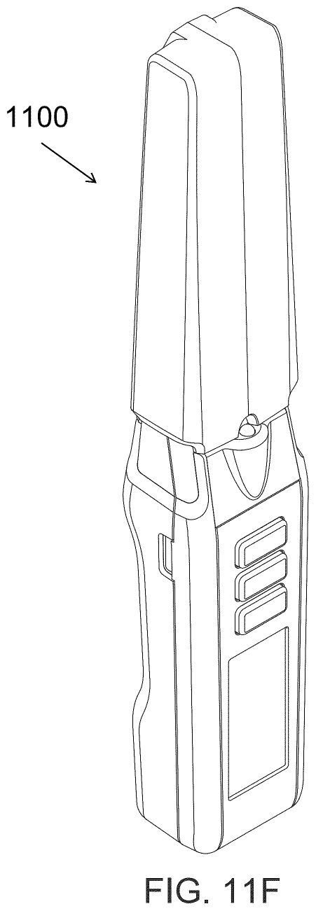

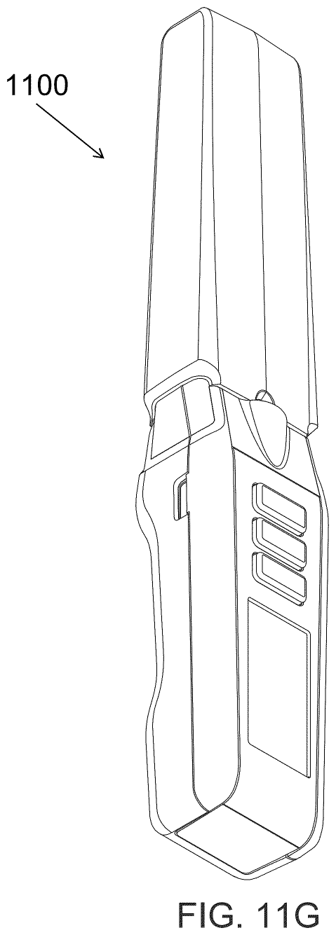

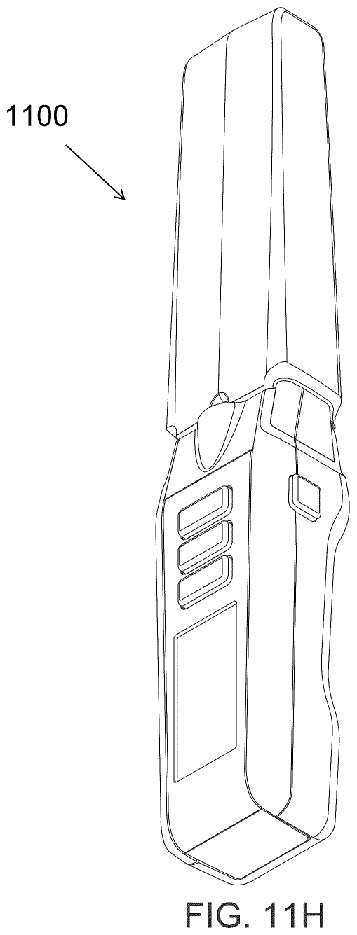

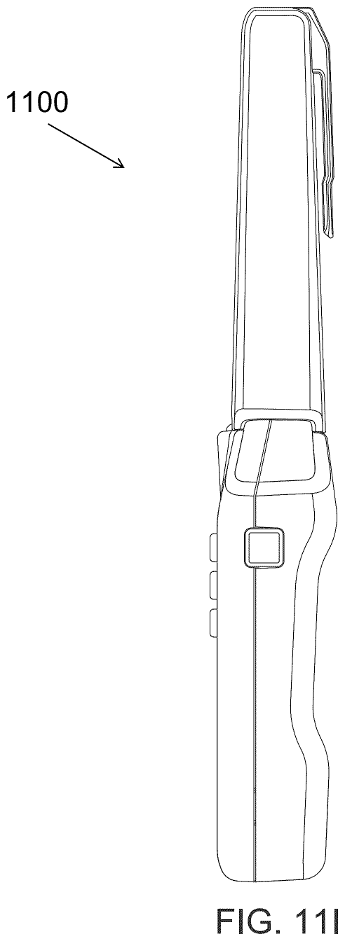

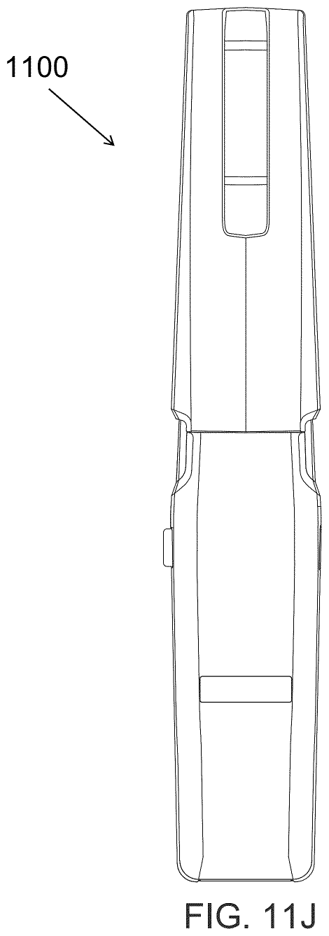

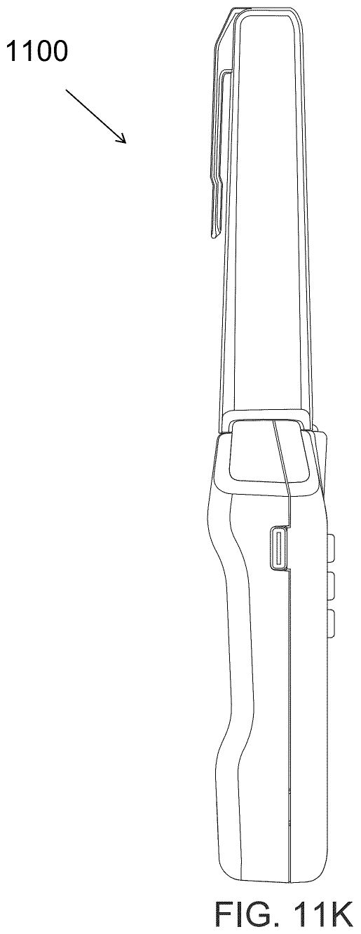

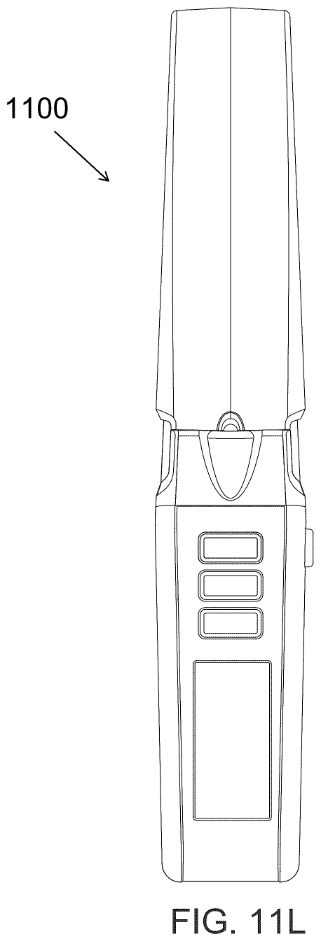

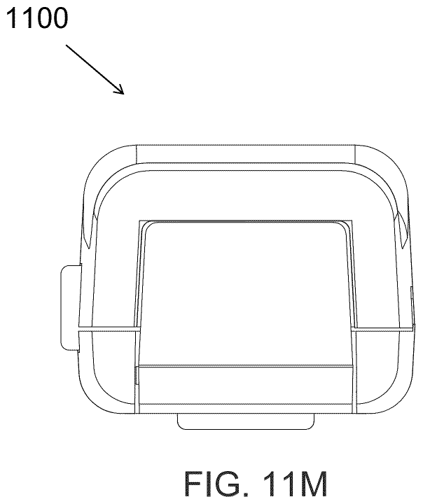

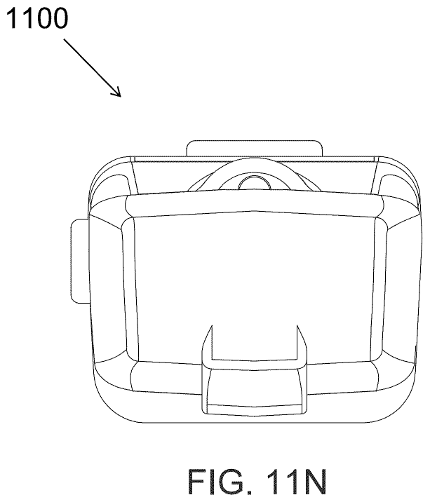

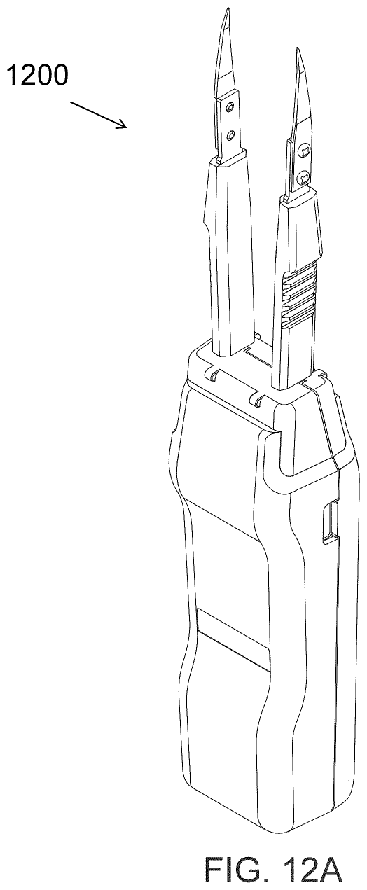

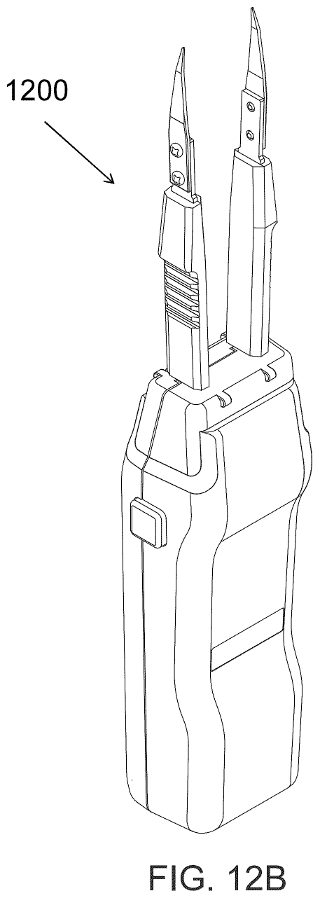

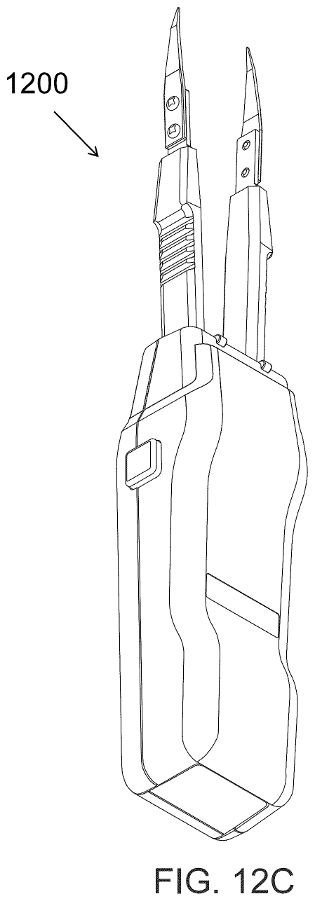

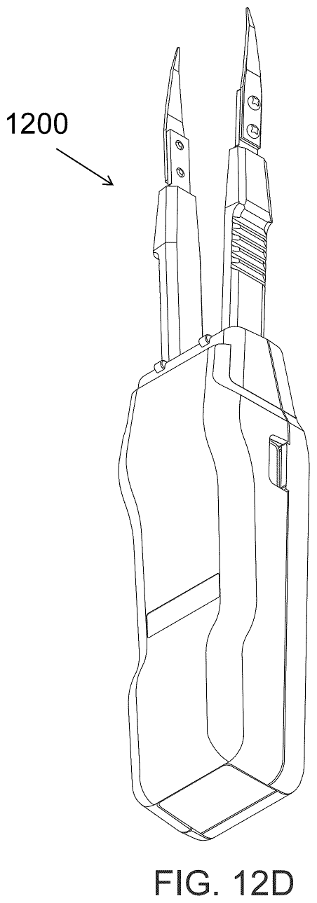

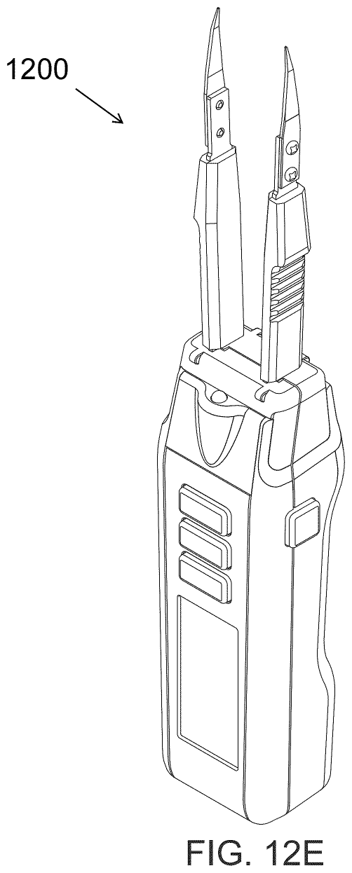

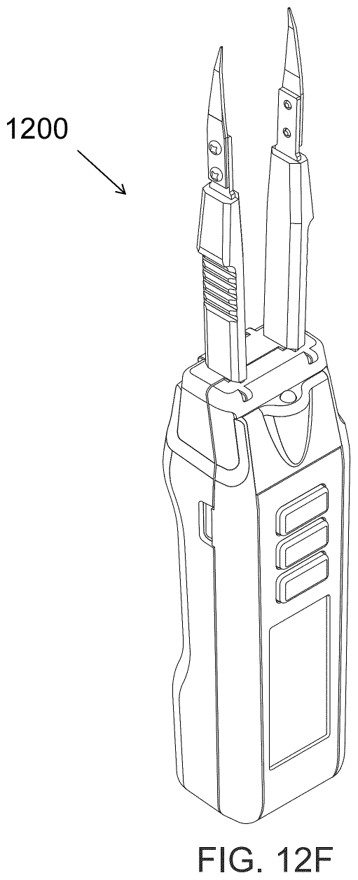

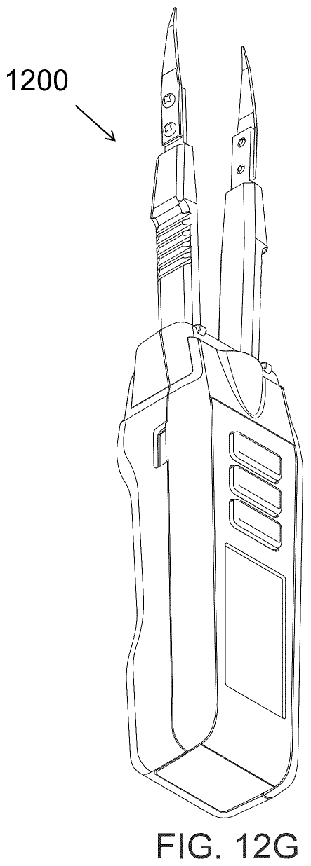

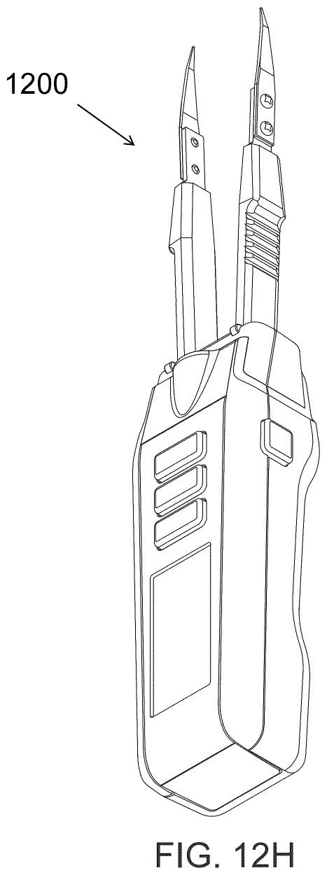

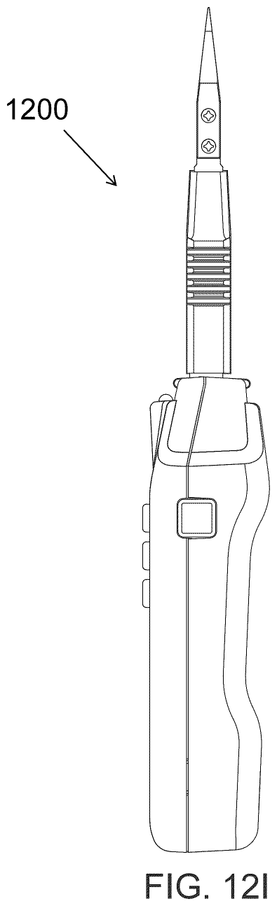

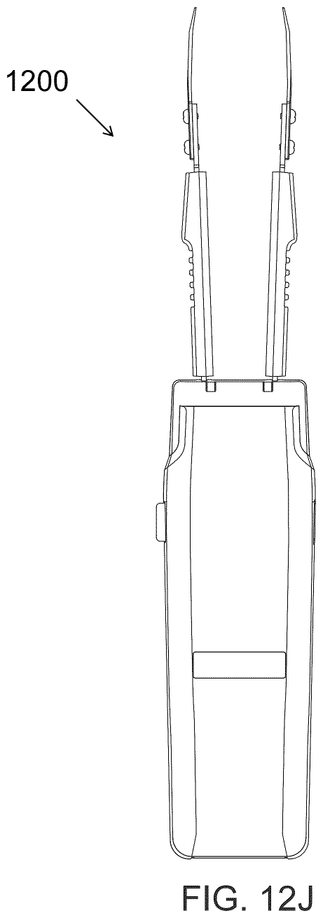

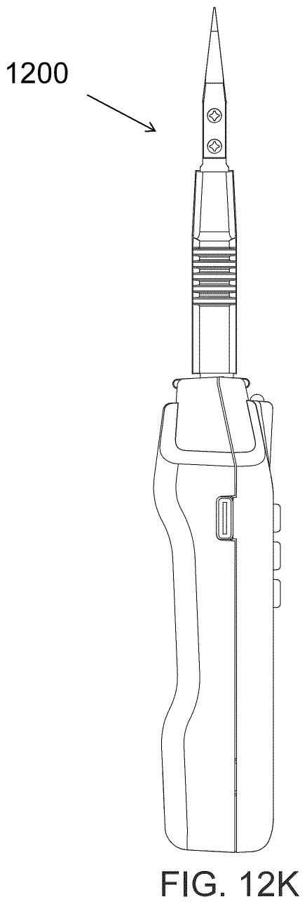

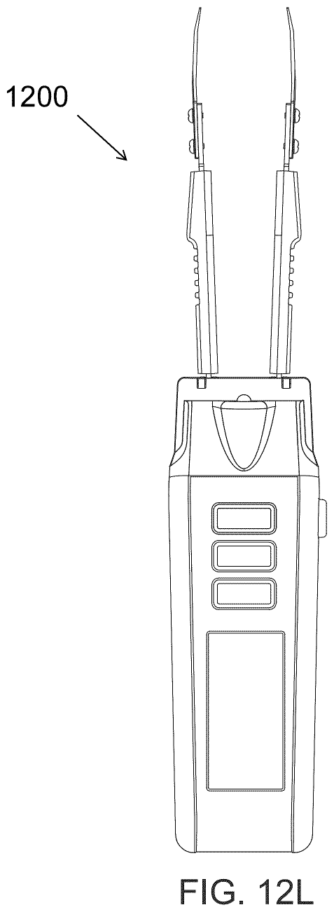

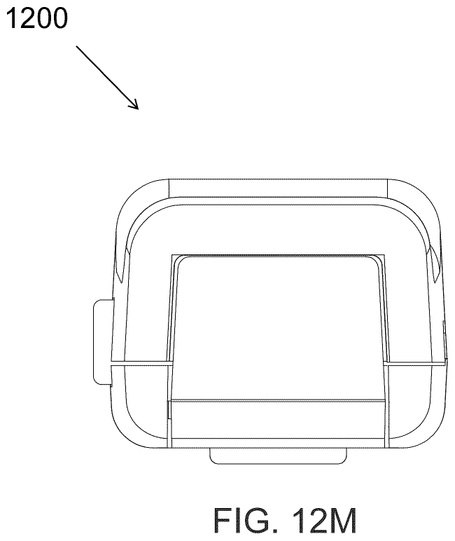

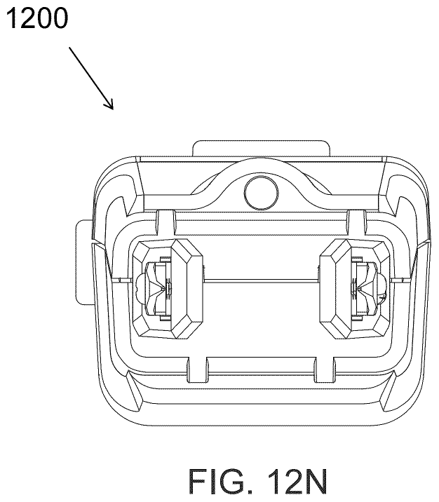

FIGS. 11A-11N depict various views of an electrical measurement device 1100 in combination with a sleeve, according to an implementation of the present disclosure. FIGS. 12A-12N depict various views of an electrical measurement device 1200, according to an implementation of the present disclosure.

Flowcharts and block diagrams depicted in the figures may illustrate functionality and operation of possible implementations of various apparatuses, systems, and methods, according to various embodiments of the present invention. In this regard, each block in the flowcharts and block diagrams may incorporate a specific function or portion of a function. Additionally, the flowcharts and block diagrams may incorporate alternative implementations and the functions noted in the block diagram may occur in a different order from that noted in the figures. For example, two blocks shown in succession may, in fact, be executed substantially concurrently, or the functions noted in the blocks may be implemented in reverse order depending on the functionality involved.

The terminology used herein is for describing particular embodiments only and is not intended to be limiting of the invention. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises,” “has,” “includes,” or “contains” one or more steps or elements possesses those one or more steps or elements but is not limited to possessing only those one or more steps or elements. Likewise, a step of a method or an element of a device that “comprises,” “has,” “includes,” or “contains” one or more features possesses those one or more features but is not limited to possessing only those one or more features. Furthermore, a device or structure that is configured in a certain way is configured in at least that way but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiments were chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method, comprising:
receiving, by a processor of an electrical measurement device, one or more user inputs selecting an electrical element from a list of electrical elements, each electrical element of the list of electrical elements having an impedance associated therewith;
accessing, from a data storage location, impedance data of the electrical element's impedance;
measuring voltage drop across an in-circuit electrical path passing through the electrical element in response to a first conductive probe element of the electrical measurement device being in contact with a first terminal of the electrical element and a second conductive probe element of the electrical measurement device being in contact with a second terminal of the electrical element;
determining, using the processor of the electrical measurement device and from the voltage drop and the impedance, amperage of the electrical element; and
transmitting a signal to one or more indicators for indicating a status of the electrical element.

2. The method of claim 1, wherein the electrical element includes a vehicle fuse, and the first terminal is a first fuse terminal, the second terminal is a second fuse terminal.

3. The method of claim 1, wherein the data storage location includes a database internal to the electrical measurement device.

4. The method of claim 1, further comprising displaying, via a user interface of the electrical element, a numerical value of the amperage of the electrical element.

5. The method of claim 1, wherein the one or more indicators include indicator lights that provide a visual indication of the status of the electrical element, the status being selected from the group consisting of “Inactive,” “Active,” and “Broken.”

6. The method of claim 1, wherein the first conductive probe element of the electrical measurement device and the second conductive probe element of the electrical measurement device are both at least partially integrated with the electrical measurement device itself.

7. The method of claim 1, wherein the electrical measurement device includes a first input for selecting a mode associated with the electrical element, a second input for turning on or off a light emitting diode (LED), and a third input for adjusting the brightness of the backlight of the display screen.

8. The method of claim 1, wherein a front face of a housing of the electrical measurement device includes a lighting element directed towards the first conductive probe element and the second terminal of the electrical element.

9. An electrical measurement device, comprising:
a first conductive probe element;
a second conductive probe element;
a processor in electrical communication with the first conductive probe element and the second conductive probe element;
a communication interface communicatively coupled to the processor; and
a data storage location communicatively coupled to the processor and storing executable code that, when executed, causes the processor to:
receive one or more user inputs selecting an electrical element from a list of electrical elements, each electrical element of the list of electrical elements having an impedance associated therewith;
access, from the data storage location, impedance data of the electrical element's impedance;
measure voltage drop across an in-circuit electrical path passing through the electrical element in response to the first conductive probe element of the electrical measurement device being in contact with a first terminal of the electrical element and the second conductive probe element of the electrical measurement device being in contact with a second terminal of the electrical element;
determine, from the voltage drop and the impedance, amperage of the electrical element; and
transmit a signal to one or more indicators for indicating a status of the electrical element.

10. The electrical measurement device of claim 9, wherein the electrical element includes a vehicle fuse, the first terminal is a first fuse terminal, and the second terminal is a second fuse terminal.

11. The electrical measurement device of claim 9, wherein the communication interface includes a user interface, and the executable code, when executed, further causes the processor to display, via the user interface, a numerical value of the amperage of the electrical element.

12. The electrical measurement device of claim 9, wherein the one or more indicators include indicator lights that provide a visual indication of the status of the electrical element, the status being selected from the group consisting of “Inactive,” “Active,” and “Broken.”

13. The electrical measurement device of claim 9, wherein the first conductive probe element of the electrical measurement device and the second conductive probe element of the electrical measurement device are both at least partially integrated with the electrical measurement device itself.

14. The electrical measurement device of claim 9, wherein the electrical measurement device includes a first input for selecting a mode associated with the electrical element, a second input for turning on or off a light emitting diode (LED), and a third input for adjusting the brightness of the backlight of the display screen.

15. A system for indicating amperage of an electrical element, the system comprising:
a processor;
a communication interface communicatively coupled to the processor; and
a data storage location communicatively coupled to the processor and storing executable code that, when executed, causes the processor to:
receive one or more user inputs selecting the electrical element from a list of electrical elements, each electrical element of the list of electrical elements having an impedance associated therewith;
access, from the data storage location, impedance data of the electrical element's impedance;
measure voltage drop across an in-circuit electrical path passing through the electrical element in response to a first conductive probe element of an electrical measurement device being in contact with a first terminal of the electrical element and a second conductive probe element of the electrical measurement device being in contact with a second terminal of the electrical element;
determine, from the voltage drop and the impedance, amperage of the electrical element; and
transmit a signal to one or more indicators for indicating a status of the electrical element.

16. The system of claim 15, wherein the electrical element includes a vehicle fuse, the first terminal is a first fuse terminal, and the second terminal is a second fuse terminal.

17. The system of claim 15, wherein the communication interface includes a user interface, and the executable code, when executed, further causes the processor to display, via the user interface, a numerical value of the amperage of the electrical element.

18. The system of claim 15, wherein the one or more indicators include indicator lights that provide a visual indication of the status of the electrical element, the status being selected from the group consisting of “Inactive,” “Active,” and “Broken.”

19. The system of claim 15, wherein the first conductive probe element of the electrical measurement device and the second conductive probe element of the electrical measurement device are both at least partially integrated with the electrical measurement device itself.

20. The system of claim 15, wherein the electrical measurement device includes a first input for selecting a mode associated with the electrical element, a second input for turning on or off a light emitting diode (LED), and a third input for adjusting the brightness of the backlight of the display screen.

21. A method, comprising:
measuring voltage drop across an in-circuit electrical path passing through an electrical element in response to a first conductive probe element that is coupled to an electrical measurement device being in contact with a first terminal of the electrical element and a second conductive probe element that is coupled to the electrical measurement device being in contact with a second terminal of the electrical element;
determining, using a processor of the electrical measurement device and from the voltage drop and from a stored impedance value corresponding to the electrical element, amperage of the electrical element; and
transmitting a signal to one or more communication interfaces for communicating the amperage.

22. The method of claim 21, wherein a range of the amperage is between 0 A-100 A.

23. The method of claim 22, wherein the range of the amperage is between 0 A-80 A.

24. The method of claim 22, wherein the range of the amperage is between 0 A-30 A.

25. The method of claim 21, wherein the stored impedance value is selected from impedance data of a plurality of impedance values stored to one or more data storage locations.

26. The method of claim 25, wherein the stored impedance value is selected based on receiving one or more user inputs identifying the electrical element.

27. A system for indicating amperage of an electrical element, the system comprising:
a processor;
a communication interface communicatively coupled to the processor; and
a data storage location communicatively coupled to the processor and storing executable code that, when executed, causes the processor to:
measure voltage drop across an in-circuit electrical path passing through an electrical element in response to a first conductive probe element that is coupled to an electrical measurement device being in contact with a first terminal of the electrical element and a second conductive probe element that is coupled to the electrical measurement device being in contact with a second terminal of the electrical element;
determine, using a processor of the electrical measurement device and from the voltage drop and from a stored impedance value corresponding to the electrical element, amperage of the electrical element; and
transmit a signal to one or more communication interfaces for communicating the amperage.

28. The system of claim 27, wherein a range of the amperage is between 0 A-100 A.

29. The system of claim 28, wherein the range of the amperage is between 0 A-80 A.

30. The system of claim 28, wherein the range of the amperage is between 0 A-30 A.

31. The system of claim 27, wherein the stored impedance value is selected from impedance data of a plurality of impedance values stored to one or more data storage locations.

32. The system of claim 31, wherein the stored impedance value is selected based on receiving one or more user inputs identifying the electrical element.
